(19) United States
(12) Patent Application Publication
(10) Pub. No.: US 2009/0311842 A1
(43) Pub. Date: Dec. 17, 2009

(54) METHOD FOR FABRICATING A SEMICONDUCTOR MEMORY DEVICE

(76) Inventor: Chih-Chiang Kuo, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/197,321

(22) Filed: Aug. 25, 2008

(30) Foreign Application Priority Data
Jun. 12, 2008 (TW) 097121900

(51) Int. Cl. H01L 21/02

(52) U.S. Cl. 438/396; 257/E21.008

(57) ABSTRACT

A method for fabricating a semiconductor memory device includes providing a substrate having thereon a conductive layer, forming an etching stop layer, a first dielectric layer and a second dielectric layer on the substrate, etching high aspect ratio hole into the etching stop layer, the first dielectric layer and the second dielectric layer to expose a portion of the conductive layer, thereafter selectively removing the first dielectric layer from the hole, thereby forming a bottle-shaped hole, then forming a conductive layer on interior surface of the bottle-shaped hole, and then stripping the first and second dielectric layers.

### BACKGROUND OF THE INVENTION

1. Field of the Invention

The present invention relates generally to the field of semiconductor memory technology. More particularly, the present invention relates to a method for fabricating a stack capacitor of a dynamic random access memory (DRAM) device.

2. Description of the Prior Art

As high density and high performance are required for a DRAM with a COB (capacitor-over-bit-line) structure, cell capacitor technology needs to be developed to provide the required performance An increase in the cell capacitance can be achieved by both using high-k materials and increasing the surface area of the storage node. Even when high-k materials are used, much effort must be focused on enlarging the storage node surface area to maximize the cell capacitance. The surface area of a storage node in a COB structure is mostly increased by increasing the height since the design rule limits the horizontal dimension of the storage node.

FIG. 1 to FIG. 5 are schematic, cross-sectional diagrams showing a conventional method of fabricating a storage node of the stack capacitor. As shown in FIG. 1, a substrate 10 such as a silicon substrate is provided. A conductive regions 12a and 12b are formed in the substrate 10. A dielectric layer 14 such as a silicon nitride layer is formed on the substrate 10. A dielectric layer 16 such as an undoped silicate glass (USG) layer is formed on the dielectric layer 14.

As shown in FIG. 2, conventional lithographic and etching processes are carried out to form high aspect ratio holes 18a and 18b in the dielectric layers 14 and 16. A clean process may be performed to remove etching byproducts or residuals from the holes 18a and 18b or from the surface of the substrate 10. It is noteworthy that at this point bowling phenomenon occurs at the upper portion of the hole 18a or hole 18b as the regions specifically indicated by dotted line 20.

As shown in FIG. 3, a conventional chemical vapor deposition (CVD) process is performed to conformally deposit a silicon layer 22 such as a doped polysilicon layer on the surface of the dielectric layer 16 and on the interior sidewalls of the holes 18a and 18b.

As shown in FIG. 4, a planarization process such as a chemical mechanical polishing (CMP) process is carried out to selectively remove the silicon layer 22 from the surface of the dielectric layer 16, leaving the silicon layer 22 inside the holes 18a and 18b intact.

Subsequently, as shown in FIG. 5, a wet etching process such as HF/NH₄F solution or BOE chemistry is used to remove the dielectric layer 16, thereby forming storage nodes 30a and 30b. The storage nodes 30a and 30b has a height H that is equal to the depth of the hole 18a or 18b, which typically ranges between 1.6 micrometers and 1.7 micrometers.

The above-described prior art method has at least the drawback in that the bowling phenomenon decreases the capacitance of the stack capacitor. It is desired to form a straight sidewall profile at the upper portions of the holes 18a and 18b when etching the holes into the dielectric layers 14 and 16. Further, the tapered holes 18a and 18b result in small bottom critical dimension A. The storage node structures 30a and 30b may collapse during the subsequent cleaning or drying processes and lead to so-called storage node bridging defects.

### SUMMARY OF THE INVENTION

It is one objective of the present invention to provide an improved method of fabricating a semiconductor memory device in order to solve the above-mentioned prior art problems.

According to the claimed invention, a method of fabricating a semiconductor memory device is provided. The method includes providing a substrate having thereon a conductive layer, forming an etching stop layer, a first dielectric layer and a second dielectric layer on the substrate, etching high aspect ratio hole into the etching stop layer, the first dielectric layer and the second dielectric layer to expose a portion of the conductive layer, thereafter selectively removing the first dielectric layer from inside the hole, thereby forming a bottle-shaped hole, then forming a conductive layer on interior surface of the bottle-shaped hole, and then stripping the first and second dielectric layers.

In one aspect, the invention method includes providing a substrate having thereon at least a conductive region; forming an etching stop layer on the substrate, a first dielectric layer on the etching stop layer, a second dielectric layer on the first dielectric layer, and a hard mask layer on the second dielectric layer; performing a lithographic and etching process to form a transitional hole through the second dielectric layer and recessed into the first dielectric layer; depositing a lining layer on the hard mask layer and on interior surface of the transitional hole; etching through the lining layer, the first dielectric layer and the etching stop layer by way of bottom of the transitional hole, thereby a high aspect ratio hole exposing a portion of the conductive region; performing a selective wet etching process to selectively remove a portion of the first dielectric layer from inside the high aspect ratio hole, thereby forming a bottle shaped hole; forming a conductive layer inside the bottle shaped hole; and removing the first and second dielectric layers to form a storage node structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic, cross-sectional diagrams showing a conventional method of fabricating a storage node of the stack capacitor.

FIG. 6 to FIG. 12 are schematic, cross-sectional diagrams showing a method of fabricating a semiconductor memory device in accordance with the first preferred embodiment of this invention.

FIG. 13 to FIG. 17 are schematic, cross-sectional diagrams showing a method of fabricating a semiconductor memory device in accordance with the second preferred embodiment of this invention.

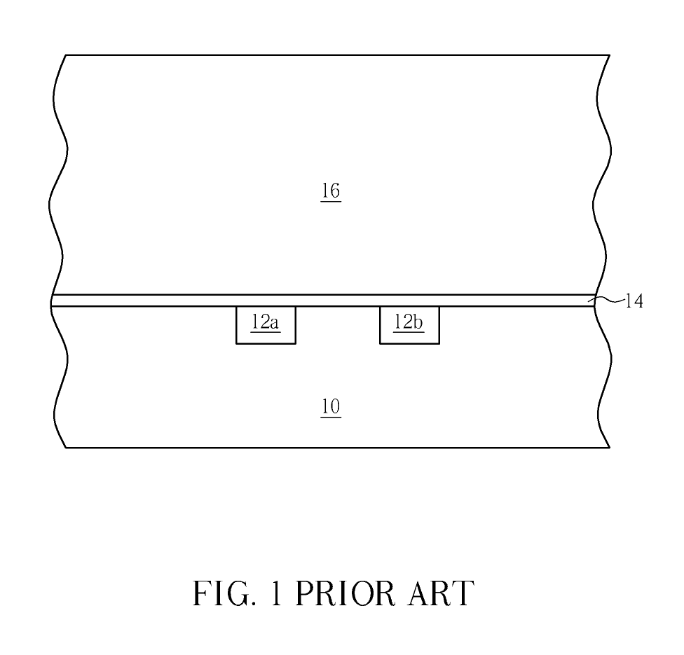

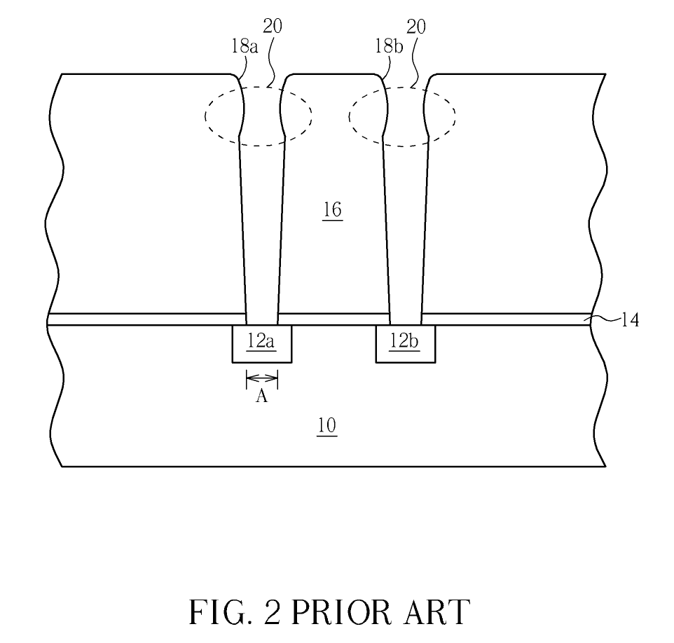

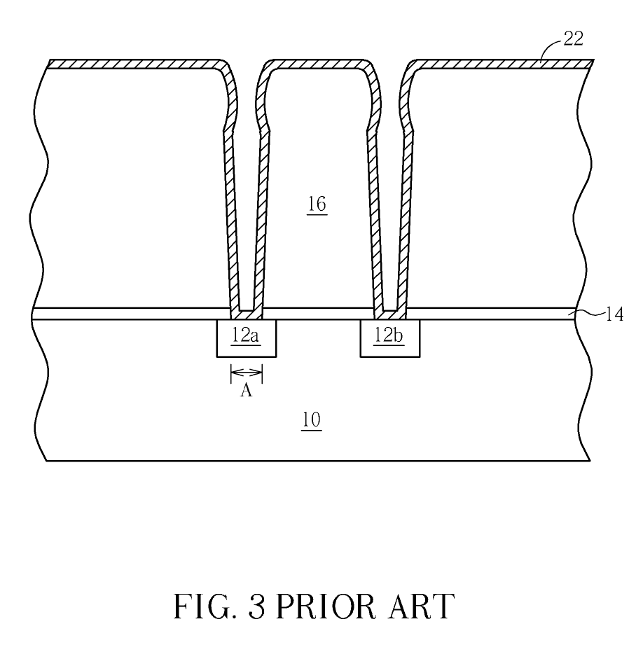

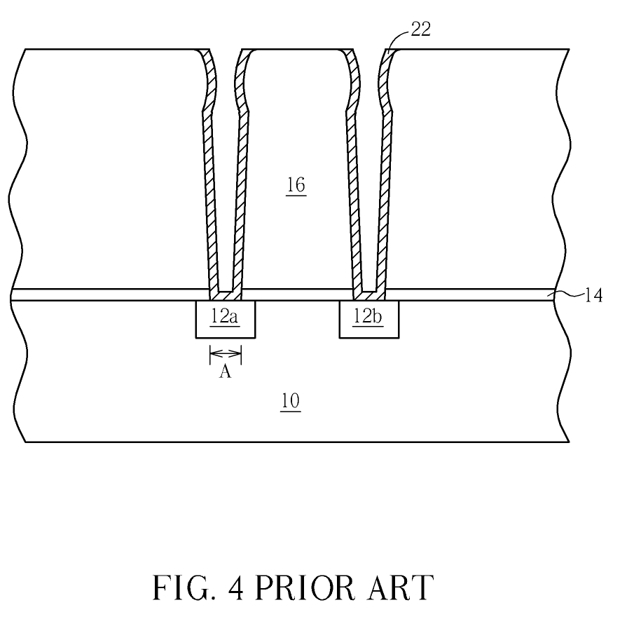

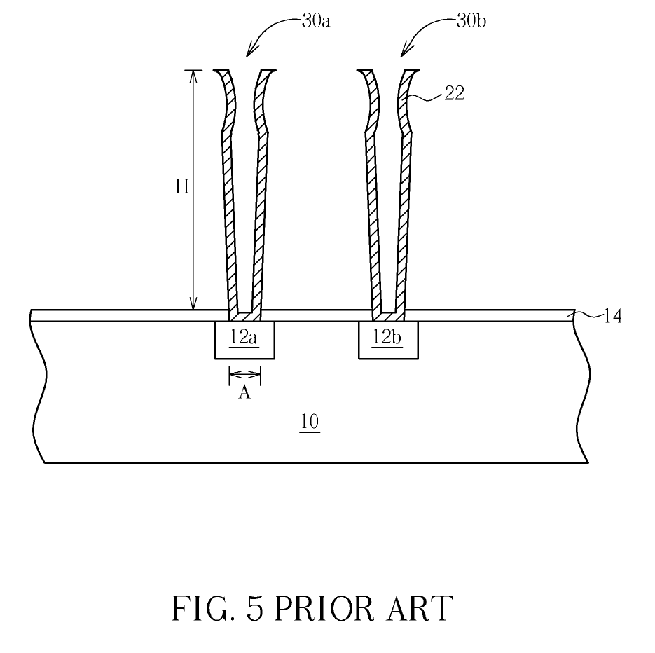

### DETAILED DESCRIPTION

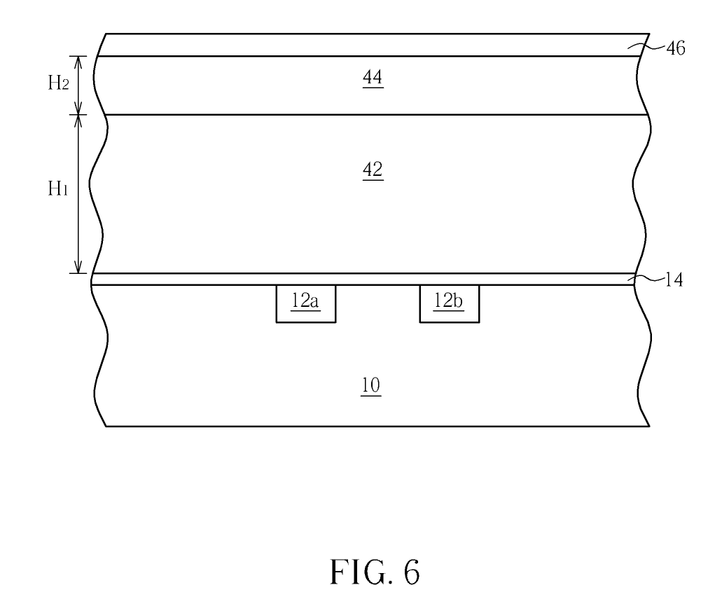

FIG. 6 to FIG. 12 are schematic, cross-sectional diagrams showing a method of fabricating a semiconductor memory device in accordance with the first preferred embodiment of this invention. As shown in FIG. 6, a substrate 10 such as a silicon substrate is provided. A conductive region 12a and a conductive region 12b are formed in the substrate 10. A dielectric layer 14 is formed on the substrate 10. A dielectric layer 42 is formed on the dielectric layer 14. A dielectric layer 44 is formed on the dielectric layer 42. The dielectric layer 14 is used as an etching stop layer and is preferably silicon nitride layer. Preferably, the dielectric layers 42 and 44 are formed of silicon oxide. According to the first preferred embodiment, a polysilicon layer 46 is formed on the dielectric layer 44.

It is noteworthy that the dielectric layers 42 and 44 have different etching rates with respect to a specific wet etchant such as diluted HF (DHF) etchant. For example, the dielectric layer 42 is BSG layer while the dielectric layer 44 is USG layer. Further, it is one important feature that the dielectric layer 42 has a thickness H₁ that is greater than the thickness H₂ of the dielectric layer 44, wherein by way of example, the thickness H₁ may range between 2 and 5 micrometers, preferably 3 micrometers, while the thickness H₂ may range between 12 and 15 micrometers, preferably 14 micrometers.

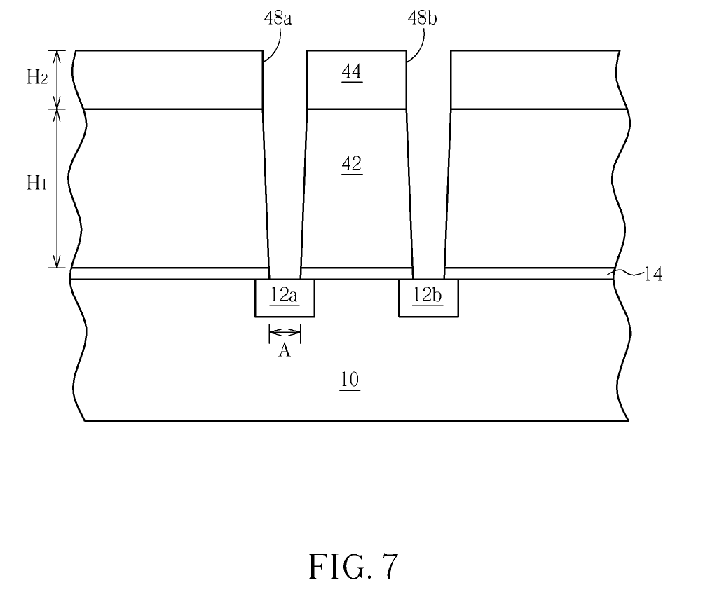

As shown in FIG. 7, conventional lithographic and etching processes are carried out to form high aspect ratio holes 48a and 48b in the dielectric layers 14, 42 and 44, which expose a portion of the conductive region 12a and a portion of the conductive region 12b respectively. The aforesaid high aspect ratio ranges between 10 and 12. A clean process may be performed to remove etching byproducts or residuals from the holes 48a and 48b or from the surface of the substrate 10. Due to the nature of the etching process, the high aspect ratio holes 48a and 48b have a tapered profile with a bottom critical dimension A. In other words, the sidewalls of the holes 48a and 48b are not vertical sidewalls.

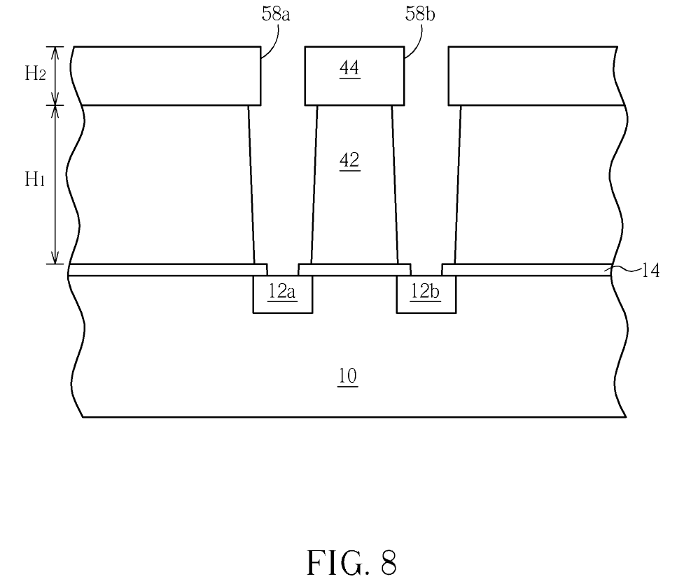

As shown in FIG. 8, a selective wet etching process is carried out to selectively remove a portion of the dielectric layer 42 from inside the holes 48a and 48b, thereby forming a bottle shaped holes 58a and 58b. According to the first preferred embodiment, the aforesaid selective wet etching process uses DHF. However, it is not recommended to use HF/NH₄F solution or other types of BOE in order to obtain a straight vertical sidewall profile and larger capacitance gain. According to the first preferred embodiment, the etching rate of the dielectric layer 42 with respect to the etchant is relatively higher comparing to that of the dielectric layer 44.

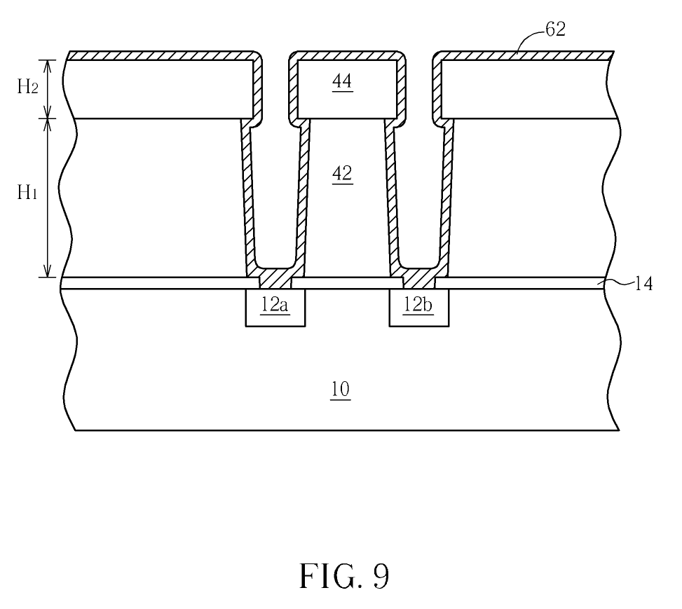

As shown in FIG. 9, a chemical vapor deposition (CVD) is performed to conformally deposit a silicon layer 62 such as a doped polysilicon layer on the surface of the dielectric layer 44 and on the interior surface of the holes 58a and 58b.

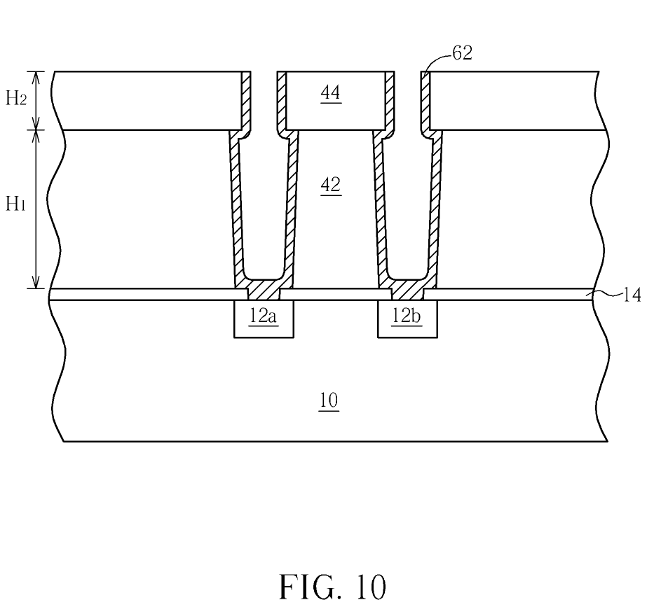

As shown in FIG. 10, a planarization process such as a chemical mechanical polishing (CMP) process is carried out to selectively remove the silicon layer 62 from the surface of the dielectric layer 44, leaving the silicon layer 62 inside the holes 58a and 58b intact.

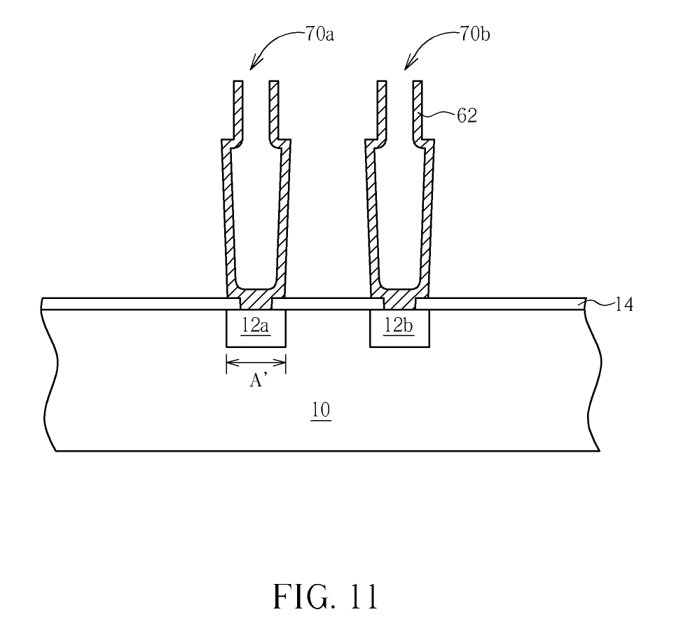

As shown in FIG. 11, thereafter, a wet etching process such as DHF solution or BOE chemistry is used to remove the dielectric layers 42 and 44, thereby forming storage nodes 70a and 70b. The storage nodes 70a and 70b has a height that is equal to the depth of the hole 58a or 58b, which typically ranges between 1.6 micrometers and 1.7 micrometers. Since the storage nodes 70a and 70b have larger bottom critical dimension A′, the storage node bridging defects are effectively avoided.

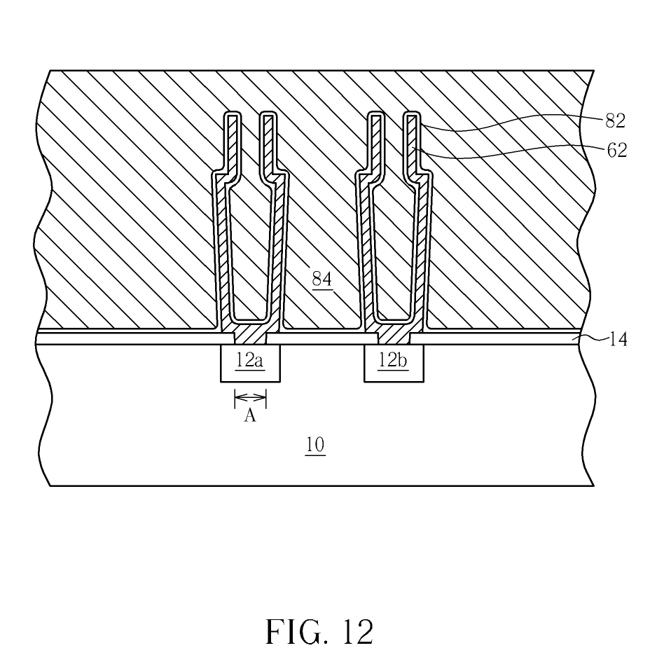

As shown in FIG. 12, a capacitor dielectric layer 82 such as a nitride-oxide (NO) dielectric or other high k dielectrics is formed on the surface of the storage nodes 70a and 70b. After the formation of the capacitor dielectric layer 82, a polysilicon layer 84 is then deposited. The polysilicon layer 84 acts as a capacitor top electrode.

The present invention has at least the following important features and advantages: (1) using at least two dielectric layers 42 and 44 to define the height and profile of the storage node and the thickness H1 of the dielectric layer 42 must be greater than the thickness H2 of the dielectric layer 44; (2) using DHF in the selective wet etching process instead of BOE in order to obtain straight sidewall profile and larger capacitor gain; and (3) the storage nodes 70a and 70b have larger bottom critical dimension A′ which avoid the storage node bridging defects.

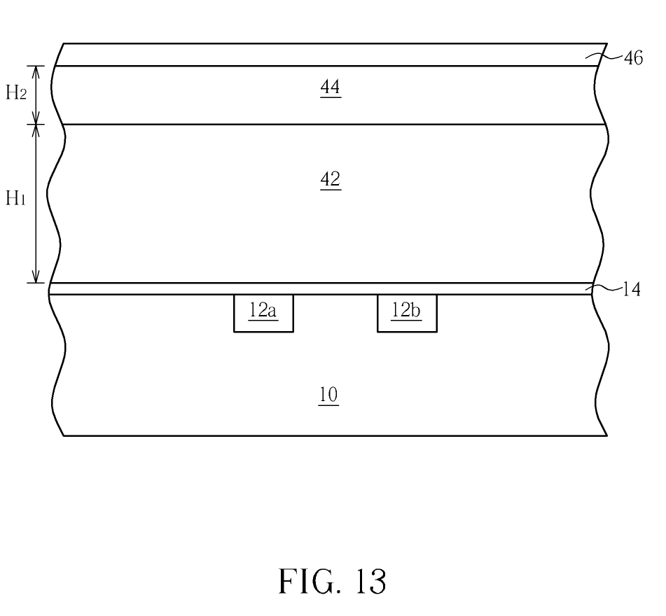

FIG. 13 to FIG. 17 are schematic, cross-sectional diagrams showing a method of fabricating a semiconductor memory device in accordance with the second preferred embodiment of this invention, wherein like numeral numbers designate like regions, layers or elements. As shown in FIG. 13, a substrate 10 such as a silicon substrate is provided. A conductive region 12a and a conductive region 12b are formed in the substrate 10. A dielectric layer 14 is formed on the substrate 10. A dielectric layer 42 is formed on the dielectric layer 14. A dielectric layer 44 is formed on the dielectric layer 42. The dielectric layer 14 is used as an etching stop layer and is preferably silicon nitride layer. Preferably, the dielectric layers 42 and 44 are formed of silicon oxide. According to the second preferred embodiment, a polysilicon layer 46 is formed on the dielectric layer 44.

According to the second preferred embodiment, the dielectric layers 42 and 44 have different etching rates with respect to a specific wet etchant such as diluted HF etchant. For example, the dielectric layer 42 is BSG layer while the dielectric layer 44 is USG layer. Further, it is one important feature that the dielectric layer 42 has a thickness H₁ that is greater than the thickness H₂ of the dielectric layer 44, wherein by way of example, the thickness H₁ may range between 2 and 5 micrometers, preferably 3 micrometers, while the thickness H₂ may range between 15 and 18 micrometers, preferably 17 micrometers.

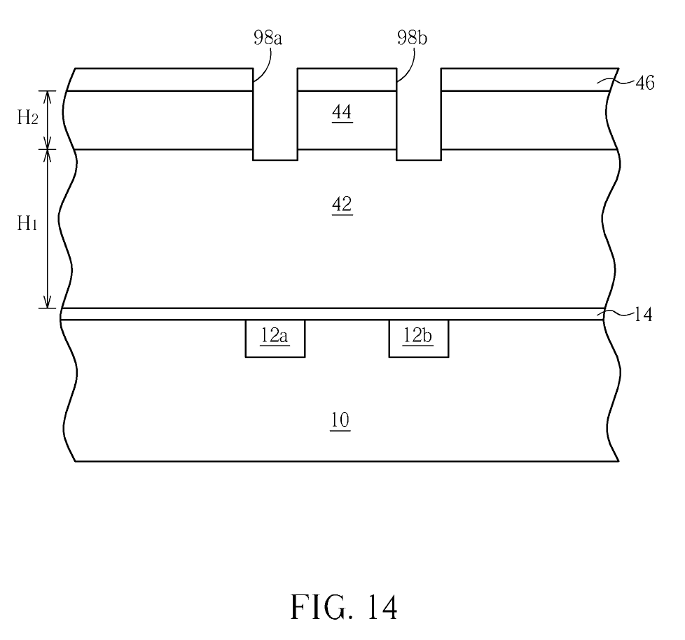

As shown in FIG. 14, conventional lithographic and etching processes are carried out to form transitional via 98a and transitional via 98b in the dielectric layers 14, 42 and 44. The transitional via 98a and transitional via 98b may be formed by first etch transferring a photoresist pattern to the polysilicon layer 46, then using the patterned polysilicon layer 46 as an etching hard mask, etching the dielectric layer 44 that is not covered with the patterned polysilicon layer 46, and the etching stops when a portion of the dielectric layer 42 is removed.

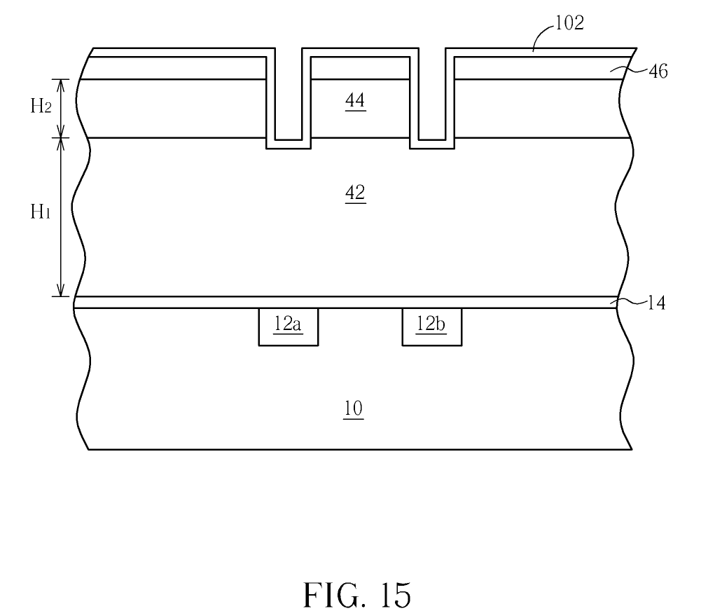

As shown in FIG. 15, a conventional CVD process is performed to conformally deposit a lining layer 102 on the interior surface of the transitional via 98a and transitional via 98b and on the surface of the remnant polysilicon layer 46. According to the second preferred embodiment, the lining layer 102 may be TEOS oxide, but not limited thereto.

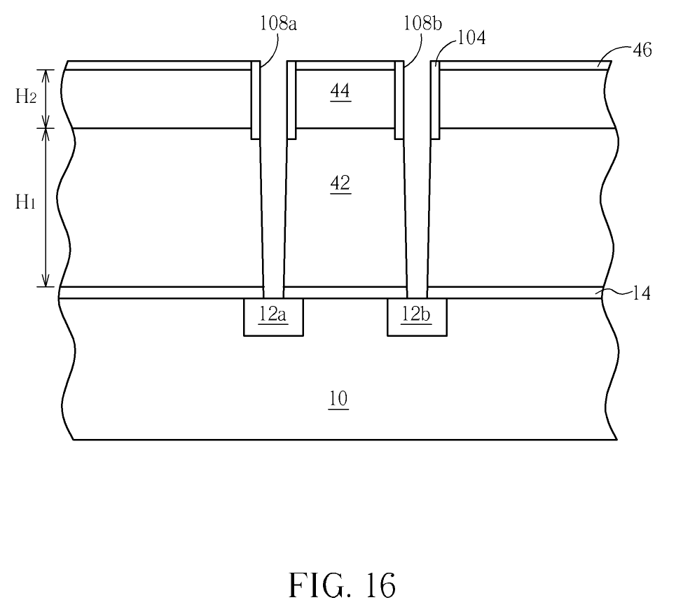

As shown in FIG. 16, an anisotropic dry etching process is then performed to etch the lining layer 102, the dielectric layer 42 and the dielectric layer 14 through the bottom of the transitional via 98a and the bottom of the transitional via 98b, thereby forming high aspect ratio holes 108a and 108b, which expose a portion of the conductive region 12a and a portion of the conductive region 12b respectively. At this point, a spacer 104 is formed on the sidewalls of the holes 108a and 108b.

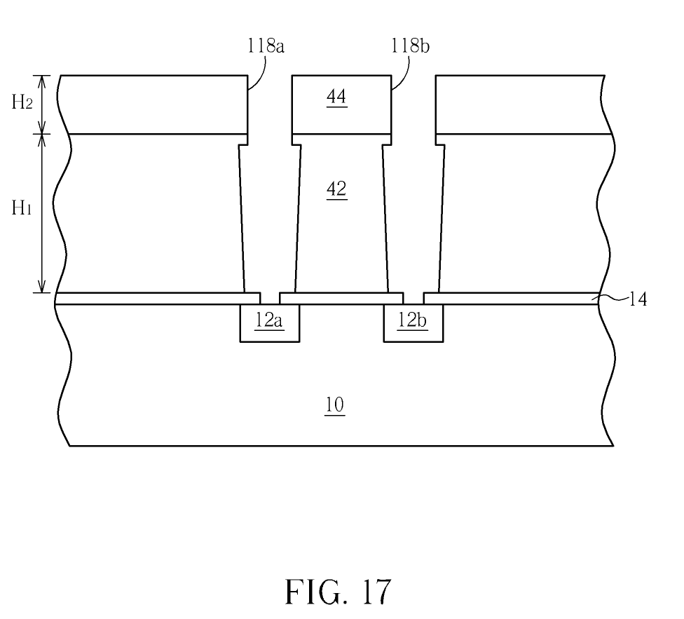

As shown in FIG. 17, a selective wet etching process is then performed to selectively remove a portion of the dielectric layer 42 from inside the holes 108a and 108b. After stripping the remaining polysilicon layer 46, bottle shaped holes 118a and 118b are formed. According to the second preferred embodiment, the aforesaid selective wet etching process uses DHF. According to the second preferred embodiment, during the aforesaid selective wet etching process, the etching rate of the dielectric layer 42 is higher than that of the dielectric layer 44. The subsequent steps are analogous to those described through FIG. 9 to FIG. 12 and are therefore omitted for the sake of simplicity.

Those skilled in the art will readily observe that numerous modifications and alterations of the device and method may be made while retaining the teachings of the invention.

What is claimed is:

1. A method of fabricating a semiconductor memory device, comprising:
providing a substrate having thereon at least a conductive region;
forming an etching stop layer on the substrate, a first dielectric layer on the etching stop layer, and a second dielectric layer on the first dielectric layer, wherein the first dielectric layer is thicker than the second dielectric layer;
performing a lithographic and etching process to form a hole in the etching stop layer, the first dielectric layer and the second dielectric layer, the hole exposing a portion of the conductive region;
performing a selective wet etching process to selectively remove a portion of the first dielectric layer from inside the hole, thereby forming a bottle shaped hole;
forming a conductive layer inside the bottle shaped hole; and
removing the first and second dielectric layers to form a storage node structure.

2. The method of claim 1 wherein the first and second dielectric layers have different etching rates with respect to a specific wet etchant.

3. The method of claim 2 wherein the specific wet etchant is diluted HF (DHF).

4. The method of claim 1 wherein the first dielectric layer comprises BSG, the second dielectric layer comprises USG.

5. The method of claim 1 wherein the first dielectric layer has a thickness between 2 and 5 micrometers, the second dielectric layer has a thickness between 12 and 15 micrometers.

6. The method of claim 1 wherein the selective wet etching process uses DHF.

7. The method of claim 1 wherein the conductive layer is a silicon layer.

8. The method of claim 1 further comprising: forming a hard mask layer on the second dielectric layer.

9. The method of claim 8 wherein the hard mask layer comprises polysilicon.

10. A method of fabricating a semiconductor memory device, comprising:
providing a substrate having thereon at least a conductive region;
forming an etching stop layer on the substrate, a first dielectric layer on the etching stop layer, a second dielectric layer on the first dielectric layer, and a hard mask layer on the second dielectric layer;
performing a lithographic and etching process to form a transitional hole through the second dielectric layer and recessed into the first dielectric layer; depositing a lining layer on the hard mask layer and on interior surface of the transitional hole;
etching through the lining layer, the first dielectric layer and the etching stop layer by way of bottom of the transitional hole, thereby a high aspect ratio hole exposing a portion of the conductive region;
performing a selective wet etching process to selectively remove a portion of the first dielectric layer from inside the high aspect ratio hole, thereby forming a bottle shaped hole;
forming a conductive layer inside the bottle shaped hole; and
removing the first and second dielectric layers to form a storage node structure.

11. The method of claim 10 wherein the first and second dielectric layers have different etching rates with respect to a specific wet etchant.

12. The method of claim 11 wherein the specific wet etchant is diluted HF (DHF).

13. The method of claim 10 wherein the first dielectric layer comprises BSG, the second dielectric layer comprises USG.

14. The method of claim 10 wherein the first dielectric layer has a thickness between 2 and 5 micrometers, the second dielectric layer has a thickness between 15 and 18 micrometers.

15. The method of claim 10 wherein the selective wet etching process uses DHF.

16. The method of claim 10 wherein the conductive layer is a silicon layer.

17. The method of claim 10 wherein the hard mask layer comprises polysilicon.

18. The method of claim 10 wherein the lining layer comprises TEOS oxide.

19. The method of claim 10 wherein the first dielectric layer is thicker than the second dielectric layer.
